(19) United States
(12) Patent Application Publication
(10) Pub. No.: US 2018/0091112 A1
(43) Pub. Date: Mar. 29, 2018

(54) DEVICE FOR ATTENUATING ELECTROMAGNETIC WAVE AND REDUCING SIDE EFFECTS USING LONGITIDINAL WAVE

(71) Applicant: UNITECH CO.,LTD., Seoul (KR)

(72) Inventor: CHANG HO KIM, Goyang-si (KR)

(73) Assignee: UNITECH CO.,LTD., Seoul (KR)

(21) Appl. No.: 15/695,358

(22) Filed: Sep. 5, 2017

(30) Foreign Application Priority Data
Sep. 29, 2016 (KR) 10-2016-0125196

(51) Int. Cl. H03H 7/24; G06F 1/16

(52) U.S. Cl. CPC H03H 7/24; G06F 1/16; G06F 1/163

(57) ABSTRACT

Disclosed is a device for attenuating an electromagnetic wave and reducing side effects comprising a housing of a memory card shape configured to be insertable into a card slot of an electronic device, an input/output interface configured to be formed in one surface of the housing and be connected with a card connector of the electronic device, a power interface unit configured to include a power supply terminal and a ground terminal among a plurality of contacts of the input/output interface and receive power from the electronic device, and an electromagnetic attenuation circuit unit configured to be provided in the housing, be connected with the power interface unit, generate a longitudinal wave signal for attenuating an electromagnetic wave of the electronic device, and transmit the longitudinal wave signal to the electronic device.

### CROSS-REFERENCE TO RELATED APPLICATIONS

A claim for priority under 35 U.S.C. § 119 is made to Korean Patent Application No. 10-2016-0125196 filed Sep. 29, 2016, in the Korean Intellectual Property Office, the entire contents of which are hereby incorporated by reference.

### BACKGROUND

Embodiments of the inventive concept described herein relate to a device for attenuating electromagnetic waves and reducing side effects on human body, and more particularly, relate to a device for attenuating electromagnetic waves and using longitudinal waves to reduce side effects on human body.

Recently, a variety of wearable devices, such as headsets and smart glasses for virtual reality (VR) or augmented reality (AR), have been developed and are being used. Such electronic devices may be closer to human bodies than conventional portable devices, such as mobile phones, in environments where the electronic devices are used. There is a definite need for a solution to harmful electromagnetic waves generated from the electronic devices. Electromagnetic waves cause side effects to human bodies such as tiredness, headache, and eye strain and even cybersickness.

### SUMMARY

Embodiments of the inventive concept provide a device for attenuating an electromagnetic wave using a longitudinal wave to reduce side effects on human body.

Embodiments of the inventive concept provide a device for attenuating an electromagnetic wave using a longitudinal wave to reduce side effects on human body, which is to be inserted into a card slot of each of various electronic devices including a smartphone and wearable devices, such as a headset or smart glass for virtual reality (VR), augmented reality (AR), or mixed reality (MR), a smart band, or a pendant by attenuating harmful electromagnetic waves generated by each of the various electronic devices.

Embodiments of the inventive concept provide a device for attenuating an electromagnetic wave using a longitudinal wave to reduce side effects on human body, which is to be inserted into a card slot of each of various electronic devices including a smartphone and wearable devices, such as a headset or smart glass for VR, AR, or MR, a smart band, or a pendant and reduce a variety of side effects on human body due to the electromagnetic wave.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic circuit diagram illustrating an electromagnetic attenuation and side effects reduction device according to an embodiment of the inventive concept;

FIG. 2 is a schematic drawing illustrating an electromagnetic attenuation and side effects reduction device of a memory card type according to an embodiment of the inventive concept;

FIG. 3 is a schematic drawing illustrating an electromagnetic attenuation and side effects reduction device of a memory card type according to another embodiment of the inventive concept;

FIG. 4 is a schematic drawing illustrating an electromagnetic attenuation and side effects reduction device of a subscriber identity module (SIM) card type according to an embodiment of the inventive concept;

FIG. 5 is a schematic drawing illustrating an electromagnetic attenuation and side effects reduction device of a SIM card type according to another embodiment of the inventive concept;

FIG. 6 is a schematic drawing illustrating an example of applying an electromagnetic attenuation and side effects reduction device to a smartphone according to an embodiment of the inventive concept;

FIG. 7 is a schematic drawing illustrating an example of applying an electromagnetic attenuation and side effects reduction device to a smart watch according to an embodiment of the inventive concept;

FIG. 8 is a schematic drawing illustrating an example of applying an electromagnetic attenuation and side effects reduction device to a headset according to an embodiment of the inventive concept;

FIG. 9 is a schematic drawing illustrating an example of applying an electromagnetic attenuation and side effects reduction device to a smart glass according to an embodiment of the inventive concept;

FIG. 10 is a schematic drawing illustrating an example of applying an electromagnetic attenuation and side effects reduction device to a smart band according to an embodiment of the inventive concept; and

FIG. 11 is a schematic drawing illustrating an example of applying an electromagnetic attenuation and side effects reduction device to a pendant according to an embodiment of the inventive concept.

FIGS. 12 and 13 are graphs illustrating the result of an experiment associated with dry eyes and sight in an electromagnetic attenuation and stress reduction device according to an embodiment of the inventive concept.

### DETAILED DESCRIPTION

Reference will now be made in detail to exemplary embodiments, examples of which are illustrated in the accompanying drawings. However, the present inventive concept may be embodied in many different forms and should not be construed as being limited to the exemplary embodiments set forth herein. Rather, these exemplary embodiments are provided so that the present disclosure will be thorough and complete, and will fully convey the scope of the present inventive concept to those skilled in the art, and the spirit and scope of the present inventive concept should be defined by the appended claims

Without separate definitions, all terms (including technical and scientific terms) used in the present description may be used for the meanings commonly understandable to those having ordinary skill in the art. In addition, the terms generally used and having definitions in dictionary, unless otherwise defined obviously in particular, should not be ideally or exaggeratedly interpreted.

The terms used in the present description are to explain the exemplary embodiments, not to limit the present invention thereto. In the present description, a singular form of word also includes a plural form thereof unless otherwise noted. The term “comprises” and/or “comprising” is not excluding the meaning that one or more elements other than the said element may exist or be added.

Hereinafter, a description will be given in detail of embodiments of the inventive concept with reference to the accompanying drawings.

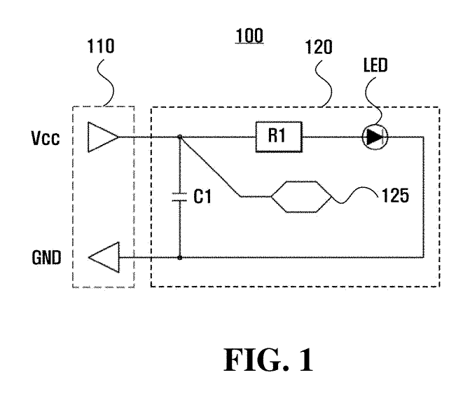

FIG. 1 is a schematic circuit diagram illustrating an electromagnetic attenuation and side effects reduction device according to an embodiment of the inventive concept.

Referring to FIG. 1, an electromagnetic attenuation and side effects reduction device 100 may include a power interface unit 110 and an electromagnetic attenuation circuit unit 120.

The power interface unit 110 may receive power from the outside and may supply the received power to the electromagnetic attenuation circuit unit 120.

The electromagnetic attenuation circuit unit 120 may include a light-emitting diode LED connected with the power interface unit 110 via a resistor R1 and a capacitor C1 connected in parallel between a power supply terminal Vcc and a ground terminal GND of the power interface unit 110. If power is supplied from the power interface unit 110, the light-emitting diode LED may be turned on. If power is not supplied from the power interface unit 110, the light-emitting diode LED may be turned off.

The electromagnetic attenuation circuit unit 120 may further include an electromagnetic attenuation pattern 125. The electromagnetic attenuation pattern 125 may be connected with the power supply terminal Vcc of the power interface unit 110. If power is supplied from the power interface unit 110, the electromagnetic attenuation pattern 125 may generate a longitudinal wave signal for attenuating an electromagnetic wave. As will be described below, the longitudinal wave signal generated by the electromagnetic attenuation pattern 125 may be transmitted to an electronic device via the power interface unit 110 to attenuate an electromagnetic wave generated by the electronic device. An embodiment is exemplified as the electromagnetic attenuation pattern 125 is formed of potassium gold cyanide (KAu(CN)2). However, embodiments are not limited thereto. Further, an embodiment is exemplified as the electromagnetic attenuation pattern 125 is formed with a hexagon shown in FIG. 1. However, embodiments are not limited thereto. For example, the electromagnetic attenuation pattern 125 may be formed with various polygons.

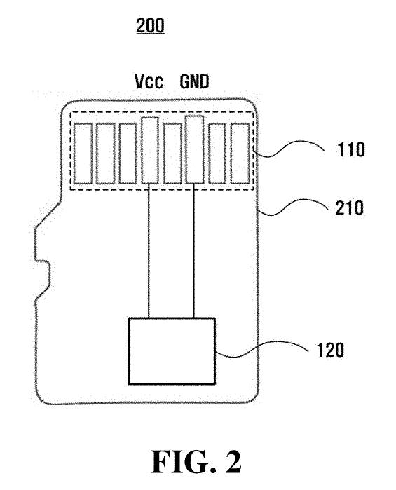

FIG. 2 is a schematic drawing illustrating an electromagnetic attenuation and side effects reduction device of a memory card type according to an embodiment of the inventive concept.

Referring to FIG. 2, an electromagnetic attenuation and side effects reduction device 200 may include a housing 210 of a memory card shape. A power interface unit 110 and an electromagnetic attenuation circuit unit 120 of an electromagnetic attenuation and side effects reduction device 100 described with reference to FIG. 1 may be placed encapsulated in the housing 210 or exposed from the housing 210.

An input/output interface may be formed in one surface of the housing 210. The input/output interface may include a plurality of contacts, and some of the plurality of contacts may function as a power supply terminal Vcc and a ground terminal GND. The power interface unit 110 may be implemented to include the power supply terminal Vcc and the ground terminal GND among the plurality of contacts of the input/output interface.

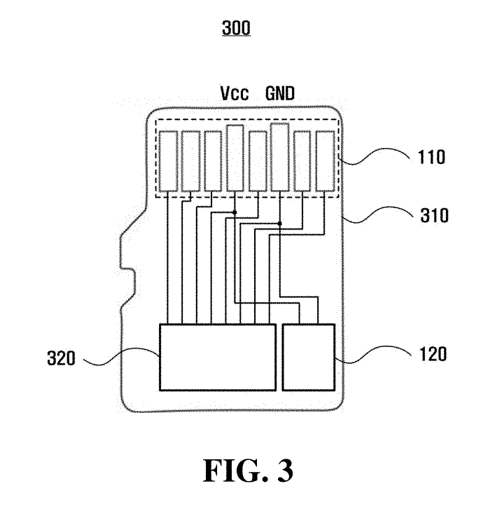

FIG. 3 is a schematic drawing illustrating an electromagnetic attenuation and side effects reduction device of a memory card type according to another embodiment of the inventive concept. For convenience of description, a description of a difference will be given on an electromagnetic attenuation and side effects reduction device of a memory card type described with reference to FIG. 2.

Referring to FIG. 3, an electromagnetic attenuation and side effects reduction device 300 may include a housing 210 of a memory card shape. A memory card circuit unit 320 may be provided in the housing 310. The memory card circuit unit 320 may include a write, read, or input/output function of data and may perform an original function of a memory card. The memory card circuit unit 320 may be connected with all of a plurality of contacts of an input/output interface. A line from each of a power supply terminal Vcc and a ground terminal GND among the plurality of contacts of the input/output interface may branches to be connected together with an electromagnetic attenuation circuit unit 120 and the memory card circuit unit 320.

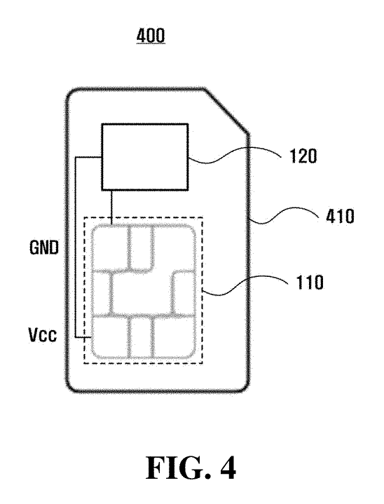

FIG. 4 is a schematic drawing illustrating an electromagnetic attenuation and side effects reduction device of a subscriber identity module (SIM) card type according to an embodiment of the inventive concept.

Referring to FIG. 4, an electromagnetic attenuation and side effects reduction device 400 may include a housing 410 of a SIM card shape. A power interface unit 110 and an electromagnetic attenuation circuit unit 120 of an electromagnetic attenuation and side effects reduction device 100 described with reference to FIG. 1 may be placed encapsulated in the housing 410 or exposed from the housing 410.

An input/output interface may be formed in one surface of the housing 410. The input/output interface may include a plurality of contacts, and some of the plurality of contacts may function as a power supply terminal Vcc and a ground terminal GND. The power interface unit 110 may be implemented to include the power supply terminal Vcc and the ground terminal GND among the plurality of contacts of the input/output interface.

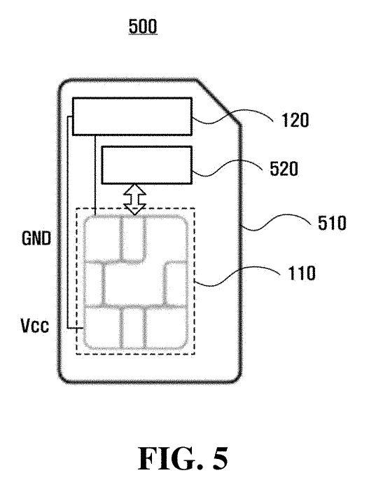

FIG. 5 is a schematic drawing illustrating an electromagnetic attenuation and side effects reduction device of a SIM card type according to another embodiment of the inventive concept. For convenience of description, a description of a difference will be given on an electromagnetic attenuation and side effects reduction device of a SIM card type described with reference to FIG. 4.

Referring to FIG. 5, an electromagnetic attenuation and side effects reduction device 500 may include a housing 510 of a SIM card shape. A SIM card circuit unit 520 may be provided in the housing 510. The SIM card circuit unit 520 may include a write, read, or input/output function of data and may perform an original function of a SIM card. The SIM card circuit unit 520 may be connected with all of a plurality of contacts of an input/output interface of the SIM card. A line from each of a power supply terminal Vcc and a ground terminal GND among the plurality of contacts may branches to be connected together with an electromagnetic attenuation circuit unit 120 and the SIM card circuit unit 520, or to be connected to be independent of the electromagnetic attenuation circuit unit 120 and the SIM card circuit unit 520.

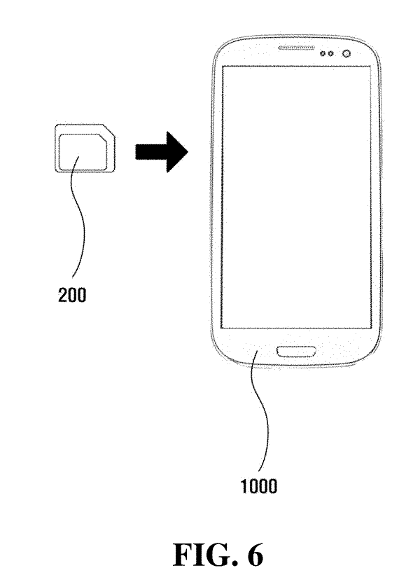

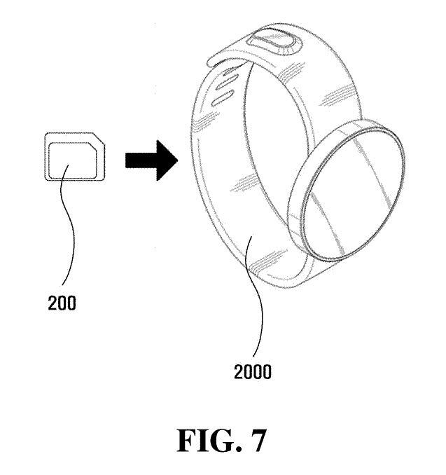

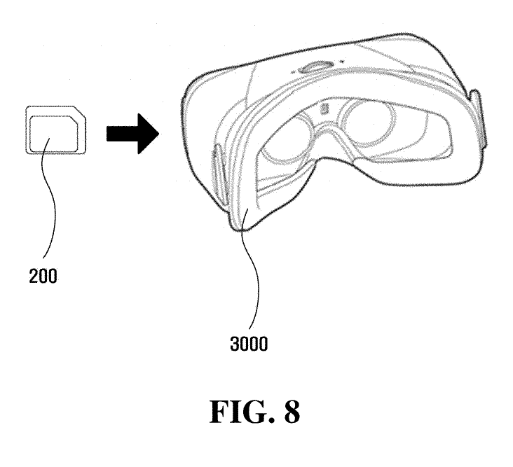

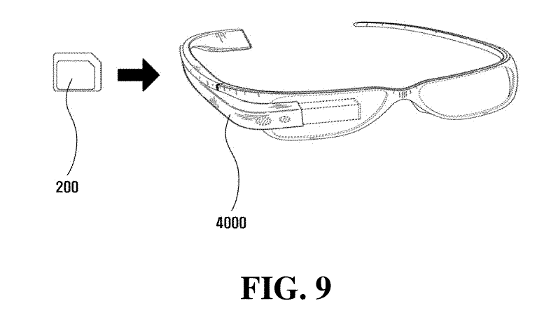

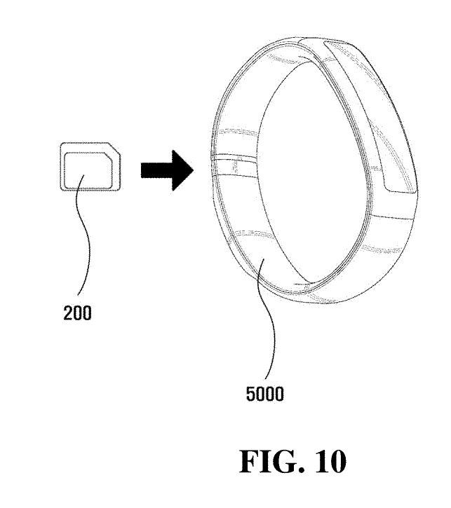

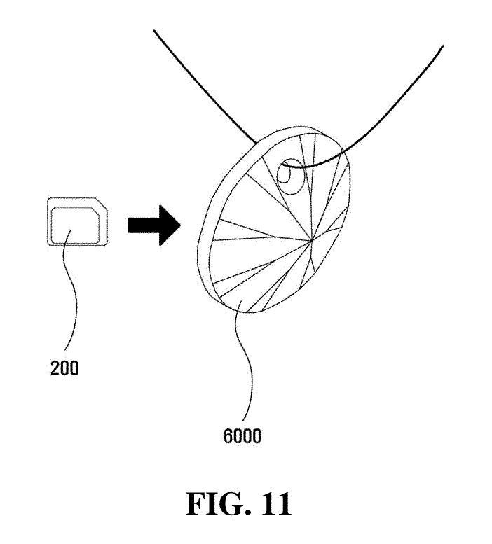

FIG. 6 is a schematic drawing illustrating an example of applying an electromagnetic attenuation and side effects reduction device to a smartphone according to an embodiment of the inventive concept. FIG. 7 is a schematic drawing illustrating an example of applying an electromagnetic attenuation and side effects reduction device to a smart watch according to an embodiment of the inventive concept. FIG. 8 is a schematic drawing illustrating an example of applying an electromagnetic attenuation and side effects reduction device to a headset according to an embodiment of the inventive concept. FIG. 9 is a schematic drawing illustrating an example of applying an electromagnetic attenuation and side effects reduction device to smart glasses according to an embodiment of the inventive concept. FIG. 10 is a schematic drawing illustrating an example of applying an electromagnetic attenuation and side effects reduction device to a smart band according to an embodiment of the inventive concept. FIG. 11 is a schematic drawing illustrating an example of applying an electromagnetic attenuation and side effects reduction device to a pendant according to an embodiment of the inventive concept.

As shown in FIGS. 6 to 11, an electromagnetic attenuation and side effects reduction device 200 may be inserted into a card slot of each of various electronic devices including a smartphone and wearable devices, such as a headset or smart glass for VR, AR, or MR, a smart band, and a pendant. The electromagnetic attenuation and side effects reduction device 200 may be combined with a card connector in the card slot of each of the electronic devices. An input/output interface of the electromagnetic attenuation and side effects reduction device 200 may be connected with the card connector of each of the electronic devices. Thus, a power interface unit 120 of FIG. 1 may receive power from each of the electronic devices. As described above, an electromagnetic attenuation pattern 125 may generate a longitudinal wave for attenuating an electromagnetic wave.

In FIGS. 6 to 11, an embodiment is exemplified as the electromagnetic attenuation and side effects reduction device 200 described with reference to FIG. 2 is applied to each of the electronic devices. However, embodiments are not limited thereto. For example, each of electromagnetic attenuation and side effects reduction devices 300, 400, and 500 described with reference to FIGS. 3 to 5 may be applied to each of the electronic devices in substantially the same manner.

Hereinafter, a description will be given of an experimental result of verifying an effect of attenuating an electromagnetic wave and reducing side effects in the device according to an embodiment of the inventive concept.

### Experimental Example 1. Experiment on an Effect of Attenuating an Electromagnetic Wave

Experimental example 1 is conducted by the Korean Testing Certification (KTC). The device according to an embodiment of the inventive concept is provided as a type of a micro SD card. To evaluate specific absorption rate (SAR) performance of the device according to an embodiment of the inventive concept using the same battery as that of a smartphone (a Samsung note 4: SKT model), the SAR performance is measured by turning on a Wi-Fi and Bluetooth mode of the smartphone and attaching an upper portion of the smartphone to a phantom location (an ear portion). A difference between an SAR measurement value if the device according to an embodiment of the inventive concept is inserted into the smartphone and an SAR measurement value if the device according to an embodiment of the inventive concept is not inserted into the smartphone is checked. An experimental procedure is performed according to “an SAR measurement standard in Notification No. 2015-23 of the National Radio Research Agency (RRA)” and a procedure described in IEC62209-1. A detailed experimental procedure is described hereinafter.

1) The unmounting of the device according to an embodiment of the inventive concept.
Test 1: after 3 minutes from a busy mode after a smartphone is connected with a base station simulator
Test 2: after 30 minutes from the busy mode after the smartphone is connected with the base station simulator
Test 3: after 60 minutes from the busy mode after the smartphone is connected with the base station simulator

2) The mounting of the device according to an embodiment of the inventive concept
Test 1: after 3 minutes from the busy mode after the smartphone is connected with the base station simulator
Test 2: after 30 minutes from the busy mode after the smartphone is connected with the base station simulator
Test 3: after 60 minutes from the busy mode after the smartphone is connected with the base station simulator

The experimental result is the following Table 1.

TABLE 1
Experimental result of an effect of
attenuating an electromagnetic wave

| | | SAR(W/kg) | | | | | |
|---|---|---|---|---|---|---|---|
| | Test | Unused | | Used | | Comparison (%) | |
| Band | Mode | 1 g | 10 g | 1 g | 10 g | 1 g | 10 g |
| | Test 1 | 0.281 | 0.212 | 0.221 | 0.167 | −21.4 | −21.2 |
| | Test 2 | 0.280 | 0.211 | 0.224 | 0.170 | −20.0 | −19.4 |
| | Test 3 | 0.279 | 0.211 | 0.225 | 0.172 | −19.4 | −18.5 |

As the experimental result, the effect of attenuating an electromagnetic wave in the device according to an embodiment of the inventive concept may be verified.

### Experimental Example 2. Experiment on an Effect Such as the Reduction of a Physical Fatigue Level

Experimental example 2 is conducted by the Korea Research Institute of Standards and Science (KRISS). The device according to an embodiment of the inventive concept is provided as a type of a micro SD card. To evaluate availability of the device according to an embodiment of the inventive concept, an experiment is conducted by selecting a physical fatigue level item, an electrooculogram item, a blood flow activity item, and a subjective fatigue level item. The device according to an embodiment of the inventive concept is inserted into a smartphone, and psychological and physiological signals are evaluated using a head mounted display (HMD). An experiment is conducted in an air conditioned room having constant temperature and humidity and is evaluated for 10 able-bodied males and females who are experimental subjects who do not suffer from a disease of the nervous system of a head portion. An order of the experiment is described hereafter. First, a physical fatigue level is measured using a flicker. Second, blinking of eyes is measured using electrooculogram. Third, blood flow activity of an eye corner point and a nose end point of a face is measured using a thermo-graphic camera. Four, a subjective fatigue level is evaluated. All the experiments use a Latin square design to reduce a carry-over effect, and post evaluation is performed after 24 hours. All the experiments are conducted before and after an HMD is used after the device according to an embodiment of the inventive concept is inserted into the smartphone. All the experiments are separately analyzed before and after the same three-dimensional (3D) content is viewed. The flicker is one of physiological measurement methods and is used to objectively evaluate a fatigue level of a central nervous system. In the present experiment, measurement is made two times respectively before and after 3D content is viewed, according to whether the device according to an embodiment of the inventive concept is used (continue in OFF of light and turn off in continuation of light). A change in potential by blinking of eyes may be recorded using a potential difference between a cornea and a retina by electrooculogram. In the present experiment, blinking of eyes is measured every one minute by attaching electrodes to upper and lower sides of each of both eyes. A face skin temperature may be evaluated by measuring a change in blood flow activity by activation of an autonomic nervous system. Particularly, since artery and vein blood vessels are concentrated around a nose, a sympathetic nerve is well reflected. After the thermo-graphic camera used in the present experiment is set to 320×240 pixels, it measures temperature by selecting an eye corner point and a nose end point in a distance of 1.5 m using a frame of 60 Hz. After a subjective fatigue level is evaluated for each experimental condition, the entire fatigue level is inquired. To maintain consistency of evaluation of the subjective fatigue level, a questionnaire is filled using a five-point Likert scale method.

The experimental result is the following Tables 2 to 5 below.

As a result of analyzing a difference between physical fatigue levels according to whether the device according to an embodiment of the inventive concept is used, a trend towards the reduction of the physical fatigue level is seen after the device according to an embodiment of the inventive concept is used (reduction of average 1.44%).

TABLE 2
Experimental result of a T-test analysis of a physical fatigue level

| | | Paired Differences | | | |
|---|---|---|---|---|---|
| Device | Content | Mean | Std. Deviation | t | p |
| Unused | Before/ | −0.400 | 1.635 | −1.094 | 0.288 |
| | After being viewed | | | | |
| Used | Before/ | −0.300 | 2.341 | −0.573 | 0.573 |
| | After being viewed | | | | |

Statistical similarity is represented (p<0.05) in a difference in blinking of eyes according to whether the device according to an embodiment of the inventive concept is used. A trend towards the reduction of a difference in blinking of eyes is seen after the device according to an embodiment of the inventive concept is used (reduction of average 17.3%).

TABLE 3
Experimental result of a T-test analysis of electrooculogram

| | | Paired Differences | | | |
|---|---|---|---|---|---|
| Device | Content | Mean | Std. Deviation | t | p |
| Unused | Before/ | 6.534 | 7.233 | 2.710 | 0.027 |
| | After being viewed | | | | |
| Used | Before/ | 4.322 | 5.194 | 2.497 | 0.037 |
| | After being viewed | | | | |

Statistical similarity is represented (p<0.1) in a difference in blood flow activity according to whether the device according to an embodiment of the inventive concept is used. A difference in blood flow activity of an eye corner point and a nose end point is reduced after the device according to an embodiment of the inventive concept is used (reduction of each of average 0.45% and average 1.63%).

TABLE 4
Experimental result of a T-test analysis of blood flow activity

| | | | Paired Differences | | | |
|---|---|---|---|---|---|---|
| | Classifi- | | | Std. | | |
| Device | cation | Content | Mean | Deviation | t | p |
| Unused | Eye corner | Before/After | −0.405 | 0.683 | −2.651 | 0.016 |
| | point | being viewed | | | | |
| Used | Eye corner | Before/After | −0.245 | 0.532 | −2.057 | 0.054 |
| | point | being viewed | | | | |
| Unused | Nose end | Before/After | −1.370 | 1.026 | −4.221 | 0.002 |
| | point | being viewed | | | | |
| Used | Nose end | Before/After | −0.820 | 0.844 | −3.071 | 0.013 |
| | point | being viewed | | | | |

As a result of analyzing a subjective fatigue level according to whether the device according to an embodiment of the inventive concept is used, a trend towards the reduction of the subjective fatigue level is seen after the device according to an embodiment of the inventive concept is used (reduction of average about 8.34%).

TABLE 5
Experimental result of a T-test analysis for a subjective
fatigue level

| | | Paired Differences | | | |
|---|---|---|---|---|---|
| Evaluation item | Device | Mean | Std. Deviation | t | p |
| Giddiness | Used/unused | 0.100 | 3.541 | 0.089 | 0.931 |
| Headache | Used/unused | 0.500 | 3.274 | 0.483 | 0.641 |
| Muscular fatigue | Used/unused | 0.800 | 2.780 | 0.910 | 0.387 |
| Face heating | Used/unused | 0.300 | 2.945 | 0.322 | 0.755 |

As the experimental result, an effect of reducing a physical fatigue level, electrooculogram, blood flow activity, and a subjective fatigue level may be verified.

### Experimental Example 3. Experiment of Comparing and Measuring Temperature

Experimental example 3 is conducted by the Korea Testing Laboratory (KTL). The device according to an embodiment of the inventive concept is provided as a type of a micro SD card. Standard atmospheric air conditions for experiment and measurement comply with 5.3. of KS C IEC 60068-1. A classification is made as a condition where the device according to an embodiment of the inventive concept is not used or a condition where the device according to an embodiment of the inventive concept is used. A temperature is measured for 1 hour for each condition. A portion where a temperature is measured is a heating part of a panel right upper end, a micro SD card mounting part, a USIM mounting part, a speaker, or the center of a battery. A stabilization and preparation time is provided by ending a smartphone before a temperature is measured, charging a battery to 100%, and leaving the smartphone for 30 minutes. After the smartphone is connected to Wi-Fi, an Internet video is played back and a temperature is measured every one minute for one hour.

The experimental result is the following Table 6 below.

TABLE 6
Experimental result of comparing and measuring temperature

| | Unused | | | Used | | |
|---|---|---|---|---|---|---|
| | Minimum | Maximum | Average | Minimum | Maximum | Average |
| Measured portion | temperature | Temperature | Temperature | temperature | Temperature | Temperature |
| Heating portion of | 28.7° C. | 29.3° C. | 28.9° C. | 27.5° C. | 28.3° C. | 27.8° C. |
| panel right upper end | | | | | | |
| Micro SD card | 29.8° C. | 30.3° C. | 30.0° C. | 28.2° C. | 28.9° C. | 28.6° C. |
| mounting part | | | | | | |
| USIM mounting part | 30.0° C. | 30.5° C. | 30.2° C. | 28.7° C. | 29.5° C. | 29.1° C. |
| Speaker | 26.2° C. | 26.7° C. | 26.4° C. | 24.9° C. | 25.8° C. | 25.5° C. |
| Center of battery | 28.1° C. | 28.5° C. | 28.3° C. | 26.3° C. | 27.2° C. | 26.9° C. |

As the experimental result, an effect of reducing a temperature of the device according to an embodiment of the inventive concept may be verified.

### Experimental Example 4. Experiment Associated with Dry Eyes and Sight

Experimental example 4 is conducted by the department of optometry in the Konyang University. The device according to an embodiment of the inventive concept is provided as a type of a micro SD card. The present experiment is conducted for 45 university students, each of which has a static visual acuity of 1.0 or more among objects with the naked eye and objects corrected by glasses, does not have a problem upon both eyes, and does not have an eye disease. After it is verified that there is abnormality upon both eyes by performing an auto-refractor for all objects prior to a test, all the experiments are conducted. In the present experiment, a phenol red test and an accommodative facility test are performed. An analysis is separately made before and after the device according to an embodiment of the inventive concept is mounted on a smartphone which uses a VR headset.

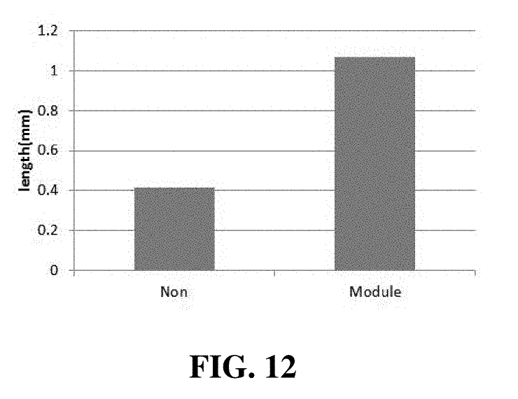

A dry eye test according to whether the device according to an embodiment of the inventive concept is used is conducted with respect to a test before a VR headset is mounted, using a phenol red. The phenol red test uses PRT-TEST (Tianjin Jingming New Technological Development Co. Ltd, China). A folded portion of a length of 3 mm in a phenol red thread is inserted into a portion corresponding to ⅓ of a lower eyelid at an eye corner. Further, a topical anesthetic is not used before the insertion. After the phenol red thread is removed after 15 seconds, a length of a portion changed to a red color is measured at intervals of millimeters. The experimental result is a graph of FIG. 12. If a VR headset is not used (Non), since a difference of a usual state in the device according to an embodiment of the inventive concept is a calculated value of 0.41 mm, a dry eye of 7% is enhanced. If the VR headset is used (module), since a difference before and after the device according to an embodiment of the inventive concept is used is a length of 0.65 mm, 5% is measured to be longer.

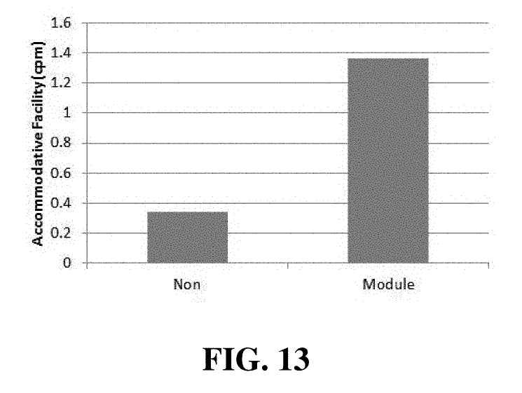

Accommodative facility means how fast an accommodative response occurs to accommodative stimulation, that is, accommodative agility. An accommodative facility test is to measure a speed of how fast and accurately an accommodative change occurs for accommodative stimulation under a single-eye or both-eye gaze. The accommodative facility is measured by installing a visual acuity test chart for testing a near vision in a distance of 33.3 cm from a testee in a state where the testee is perfectly corrected and adjusting bright illumination to the visual acuity test chart. The experimental result is a graph of FIG. 13. If the device according to an embodiment of the inventive concept is used, the accommodative facility is increased. This indicates that both eyes respond more quickly and accurately. If the VR headset is not used (Non), since a difference of a usual state is 0.34 cpm, 30% is enhanced in the device according to an embodiment of the inventive concept. If the VR headset is used (Module), since a difference before and after the device according to an embodiment of the inventive concept is used is 1.36 cpm, 52% is increased.

As the experimental result, an effect associated with dry eyes and accommodative facility in the device according to an embodiment of the inventive concept may be verified.

Although not clearly shown, the electromagnetic attenuation and side effects reduction device according to an embodiment of the inventive concept may be inserted into a card slot of each of various electronic devices which are not exemplified herein to attenuate harmful electromagnetic waves generated by each of the electronic devices in the same manner and reduce a variety of side effects of a human body due to electromagnetic waves in the same manner.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A device for attenuating an electromagnetic wave and reducing side effects, the device comprising:
a housing of a memory card shape configured to be insertable into a card slot of an electronic device;
an input/output interface configured to be formed in one surface of the housing and be connected with a card connector of the electronic device;
a power interface unit configured to include a power supply terminal and a ground terminal among a plurality of contacts of the input/output interface, and receive power from the electronic device; and
an electromagnetic attenuation circuit unit configured to be provided in the housing, be connected with the power interface unit, generate a longitudinal wave signal for attenuating an electromagnetic wave of the electronic device, and transmit the longitudinal wave signal to the electronic device.

2. The device of claim 1, further comprising:
a memory card circuit unit configured to be provided in the housing, be connected with the plurality of contacts of the input/output interface, and perform a write, read, or input/output function of data.

3. The device of claim 1, wherein the electronic device is a wearable device.

4. The device of claim 3, wherein the wearable device comprises at least one of a headset or smart glasses for virtual reality (VR), augmented reality (AR), or mixed reality (MR), a smart band, or a pendant.

5. A device for attenuating an electromagnetic wave and reducing side effects, the device comprising:
a housing of a subscriber identity module (SIM) card shape configured to be insertable into a card slot of an electronic device;
an input/output interface configured to be formed in one surface of the housing and be connected with a card connector of the electronic device;
a power interface unit configured to include a power supply terminal and a ground terminal among a plurality of contacts of the input/output interface and receive power from the electronic device; and
an electromagnetic attenuation pattern configured to be provided in the housing, be connected with the power interface unit, generate a longitudinal wave signal for attenuating an electromagnetic wave of the electronic device, and transmit the longitudinal wave signal to the electronic device.

6. The device of claim 5, further comprising:
a SIM card circuit unit configured to be provide in the housing, be connected with the plurality of contacts of the input/output interface, and perform a write, read, or input/output function of data.

7. The device of claim 5, wherein the electronic device is a wearable device.

8. The device of claim 7, wherein the wearable device comprises at least one of a headset or smart glasses for VR, AR, or MR, a smart band, or a pendant.
